(19) United States
(12) Patent Application Publication
(10) Pub. No.: US 2009/0236724 A1
(43) Pub. Date: Sep. 24, 2009

(54) IC PACKAGE WITH WIREBOND AND FLIPCHIP INTERCONNECTS ON THE SAME DIE WITH THROUGH WAFER VIA

(75) Inventor: Tonglong Zhang, Tustin, CA (US)

Correspondence Address: FIALA & WEAVER, P.L.L.C.;C/O CPA GLOBAL, P.O. BOX 52050, MINNEAPOLIS, MN, 55402, US

(73) Assignee: BROADCOM CORPORATION, Irvine, CA (US)

(21) Appl. No.: 12/051,623

(22) Filed: Mar. 19, 2008

(51) Int. Cl. H01L 23/48; H01L 21/00

(52) U.S. Cl. 257/690; 438/108; 257/E23.011

(57) ABSTRACT

Integrated circuit dies, integrated circuit packages, and methods for assembling the same are provided. An integrated circuit package includes a substrate, an integrated circuit die, a plurality of electrically conductive bump interconnects, an electrically conductive material, and one or more bond wires. The electrically conductive bump interconnects mount a first surface of the die to a first surface of the substrate. The electrically conductive material forms an electrically conductive path from a first electrically conductive feature on the first surface of the die to a second electrically conductive feature on the second surface of the die. The bond wire couples the second electrically conductive feature to a third electrically conductive feature on the first surface of the substrate. In this manner, flip chip bump interconnects and bond wires are available to interface signals of the die with the substrate.

### BACKGROUND OF THE INVENTION

1. Field of the Invention

The present invention relates to integrated circuit packaging technology, and more particularly to flip chip integrated circuit package substrates.

2. Background Art

Integrated circuit (IC) chips or dies from semiconductor wafers are typically interfaced with other circuits using a package that can be attached to a printed circuit board (PCB). One such type of IC die package is a ball grid array (BGA) package. BGA packages provide for smaller footprints than many other package solutions available today. A BGA package has an array of solder ball pads located on a bottom external surface of a package substrate. Solder balls are attached to the solder ball pads. The solder balls are reflowed to attach the package to the PCB.

In some BGA packages, a die is attached to the substrate of the package (e.g., using an adhesive), and signals of the die are interfaced with electrical features (e.g., bond fingers) of the substrate using wire bonds. In such a BGA package, wire bonds are connected between signal pads/terminals of the die and electrical features of the substrate. In another type of BGA package, which may be referred to as a “flip chip package,” a die may be attached to the substrate of the package in a “flip chip” orientation. In such a BGA package, solder bumps are formed on the signal pads/terminals of the die, and the die is inverted (“flipped”) and attached to the substrate by reflowing the solder bumps so that they attach to corresponding pads on the surface of the substrate.

As integrated circuits are becoming increasingly more complex, the number of power, ground, and I/O pads/terminals of integrated circuit dies is also increasing. It is becoming increasingly more difficult to interface this increased number of power, ground, and I/O pads/terminals of integrated circuit dies with package substrates.

### BRIEF SUMMARY OF THE INVENTION

Integrated circuit dies, integrated circuit packages, and methods for assembling the same are provided. An integrated circuit die is configured to enable flip chip mounting of the die to a substrate, and to allow bond wire connections between the die and substrate. Such a configuration may enable greater numbers of signals (e.g., power, ground, I/O, test, etc.) of the die to be interfaced with the substrate in an integrated circuit package.

In a first aspect, an integrated circuit package includes a substrate, an integrated circuit die, a plurality of electrically conductive interconnects (e.g., bump interconnects), an electrically conductive material, and a bond wire. The electrically conductive interconnects mount the die to a first surface of the substrate (e.g., in a flip chip manner). The electrically conductive material forms an electrically conductive path from a first electrically conductive feature on the first surface of the die to a second electrically conductive feature on the second surface of the die. The bond wire couples the second electrically conductive feature of the die to a third electrically conductive feature on the first surface of the substrate.

In one example, a via is present through the die. The electrically conductive material is in the via, such that the electrically conductive path from the first electrically conductive feature to the second electrically conductive feature is routed through the via.

In another example, the integrated circuit die has an edge that includes an indentation that extends between the first and second surfaces of the die. The electrically conductive material is in the indentation, such that the electrically conductive path from the first electrically conductive feature to the second electrically conductive feature is routed through the indentation.

In another aspect, a method for assembling integrated circuit packages is provided. A semiconductor wafer has a plurality of integrated circuit regions. A plurality of holes is formed in a first surface of the wafer between the integrated circuit regions. An electrically conductive material is applied to the semiconductor wafer to form electrically conductive paths through the holes (e.g., to form electrically conductive vias). Each electrically conductive path is formed through a hole between a first electrically conductive feature on the first surface of the wafer and a second electrically conductive feature on the second surface of the wafer. A plurality of electrically conductive interconnects (e.g., bump interconnects) is formed on the first surface of the wafer in each integrated circuit region. The integrated circuit regions are separated from the wafer to form a plurality of integrated circuit dies. Each integrated circuit die is mounted to a corresponding package substrate using the electrically conductive interconnects. A bond wire is coupled between the second electrically conductive feature of each integrated circuit die to a third electrically conductive feature of the corresponding substrate.

In one aspect, separating the integrated circuit regions from the wafer leaves intact vias in the resulting integrated circuit dies. The electrically conductive paths include the electrically conductive material in the vias.

In another aspect, separating the integrated circuit regions from the wafer separates the vias into semicylindrical indentations in edges of the dies. The electrically conductive paths include the electrically conductive material in the indentations.

These and other objects, advantages and features will become readily apparent in view of the following detailed description of the invention. Note that the Summary and Abstract sections may set forth one or more, but not all exemplary embodiments of the present invention as contemplated by the inventor(s).

### BRIEF DESCRIPTION OF THE DRAWINGS/FIGURES

The accompanying drawings, which are incorporated herein and form a part of the specification, illustrate the present invention and, together with the description, further serve to explain the principles of the invention and to enable a person skilled in the pertinent art to make and use the invention.

FIG. 1 shows a cross-sectional side view of an example wirebond BGA package.

FIG. 2 shows a bottom view of the BGA package of FIG. 1.

FIG. 3 shows a cross-sectional side view of an example flip chip BGA package.

FIG. 4 shows a view of a surface of the substrate of the flip chip BGA package of FIG. 3.

FIGS. 5 and 6 show views of a BGA package, according to an example embodiment of the present invention.

FIG. 7 shows a flowchart providing a process for assembling integrated circuit packages, according to embodiments of the present invention.

FIG. 8 shows a view of a surface of an example wafer.

FIG. 9 shows a side cross-sectional view of a portion of the wafer of FIG. 8, showing two integrated circuit regions.

FIGS. 10 and 11 show the wafer portion of FIG. 9 with holes formed therein, according to example embodiments of the present invention.

FIGS. 12 and 13 show views of the top and bottom surfaces of the portion of the wafer shown in FIG. 8, according to an example embodiment of the present invention.

FIGS. 14 and 15 show views of the top and bottom surfaces of the portion of the wafer shown in FIG. 8, according to an example embodiment of the present invention.

FIGS. 16 and 17 show integrated circuit dies having electrically conductive paths formed between surfaces of the dies, according to example embodiments of the present invention.

FIG. 18 shows an example indentation formed in an edge of a die that forms an electrically conductive path, according to an embodiment of the present invention.

FIG. 19 shows a side cross-sectional view of a BGA package that includes the integrated circuit die of FIG. 17, according to an example embodiment of the present invention.

The present invention will now be described with reference to the accompanying drawings. In the drawings, like reference numbers indicate identical or functionally similar elements. Additionally, the left-most digit(s) of a reference number identifies the drawing in which the reference number first appears.

### DETAILED DESCRIPTION OF THE INVENTION

### Introduction

The present specification discloses one or more embodiments that incorporate the features of the invention. The disclosed embodiment(s) merely exemplify the invention. The scope of the invention is not limited to the disclosed embodiment(s). The invention is defined by the claims appended hereto.

References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

Furthermore, it should be understood that spatial descriptions (e.g., “above,” “below,” “up,” “left,” “right,” “down,” “top,” “bottom,” “vertical,” “horizontal,” etc.) used herein are for purposes of illustration only, and that practical implementations of the structures described herein can be spatially arranged in any orientation or manner.

### Example Integrated Circuit Packages

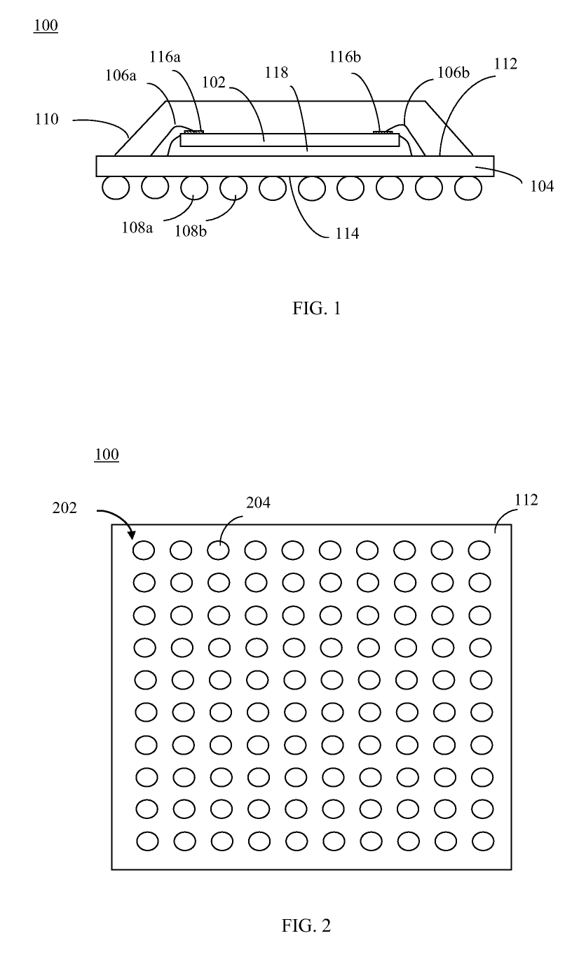

Example integrated circuit packages are described in this section. FIG. 1 shows a cross-sectional view of an example BGA package 100. BGA package 100 may be a plastic BGA (PBGA) package, a flex BGA package, a ceramic BGA package, a fine pitch BGA (FPBGA or FBGA) package, or other type of BGA package. BGA package 100 includes an integrated circuit die/chip 102, a substrate 104, bond wires (also known as “wire bonds”) 106, a plurality of solder balls 108, and an encapsulating material 110. Substrate 104 has a first (e.g., top) surface 112 that is opposed to a second (e.g., bottom) surface 114 of substrate 104. As shown in FIG. 1, die 102 is mounted to first surface 112 of substrate 104. Die 102 may be mounted to substrate 104 using an adhesive material 118.

As shown in FIG. 1, a plurality of bond wires 106 are coupled between pads/terminals 116 of die 102 and electrically conductive features, such as traces, bond fingers, etc. (not shown in FIG. 1), at first surface 112 of substrate 104. For example, a first bond wire 106a is connected between a terminal 116a and first surface 112 of substrate 104, and a second bond wire 106b is connected between a terminal 116b and first surface 112 of substrate 104. Any number of bond wires 106 may be present, depending on a number of signals (at terminals 116) of die 102 to be coupled to conductive features of first surface 112 of substrate 104. Bond wires 106 may be wires formed of any suitable electrically conductive material, including a metal such as gold, silver, copper, aluminum, other metal, or combination of metals/alloy. Bond wires 106 may be attached according to wire bonding techniques and mechanisms well known to persons skilled in the relevant art(s).

As further shown in FIG. 1, encapsulating material 110 covers die 102 and bond wires 106 on first surface 112 of substrate 104. Encapsulating material 110 protects die 102 and bond wires 106 from environmental hazards. Encapsulating material 110 may be any suitable type of encapsulating material, including an epoxy, a mold compound, etc. Encapsulating material 110 may be applied in a variety of ways, including by a saw singulation technique, injection into a mold, etc.

A plurality of solder balls 108 (including solder balls 108a and 108b indicated in FIG. 1) is attached to second surface 114 of substrate 104. FIG. 2 shows a bottom view of second surface 114 of substrate 104. Solder balls 108 are not shown in FIG. 2. Instead, in FIG. 2, second surface 114 of substrate 104 includes an array 202 of solder balls pads 204. In the example of FIG. 2, array 202 includes one hundred solder ball pads 204 arranged in a 10 by 10 array. In other implementations, array 202 may include fewer or greater numbers of solder ball pads 204 arranged in any number of rows and columns. Solder ball pads 204 are attachment locations for solder balls 108 (shown in FIG. 1) on package 100. Solder ball pads 204 are electrically coupled through substrate 104 (e.g., by electrically conductive vias and/or routing) to the electrically conductive features (e.g., traces, bond fingers, contact regions, etc.) of first surface 112 of substrate 104 to enable signals of die 102 to be electrically connected to solder balls 108. Note that FIG. 2 shows a full array of solder ball pads 204. In some embodiments, array 202 of solder ball pads 204 may be missing some pads 204, so that array 202 is not necessarily a full array of solder balls 108 on second surface 114.

Substrate 104 may include one or more electrically conductive layers (such as at first surface 112) that are separated by one or more electrically insulating layers. An electrically conductive layer may include traces/routing, bond fingers, contact pads, and/or other electrically conductive features. For example, BGA substrates having one electrically conductive layer, two electrically conductive layers, or four electrically conductive layers are common. The electrically conductive layers may be made from an electrically conductive material, such as a metal or combination of metals/alloy, including copper, aluminum, tin, nickel, gold, silver, etc. In embodiments, substrate 104 may be rigid or may be flexible (e.g., a “flex” substrate). The electrically insulating layer(s) may be made from ceramic, plastic, tape, and/or other suitable materials. For example, the electrically insulating layer(s) of substrate 104 may be made from an organic material such as BT (bismaleimide triazine) laminate/resin, a flexible tape material such as polyimide, a flame retardant fiberglass composite substrate board material (e.g., FR-4), etc. The electrically conductive and non-conductive layers can be stacked and laminated together, or otherwise attached to each other, to form substrate 104, in a manner as would be known to persons skilled in the relevant art(s).

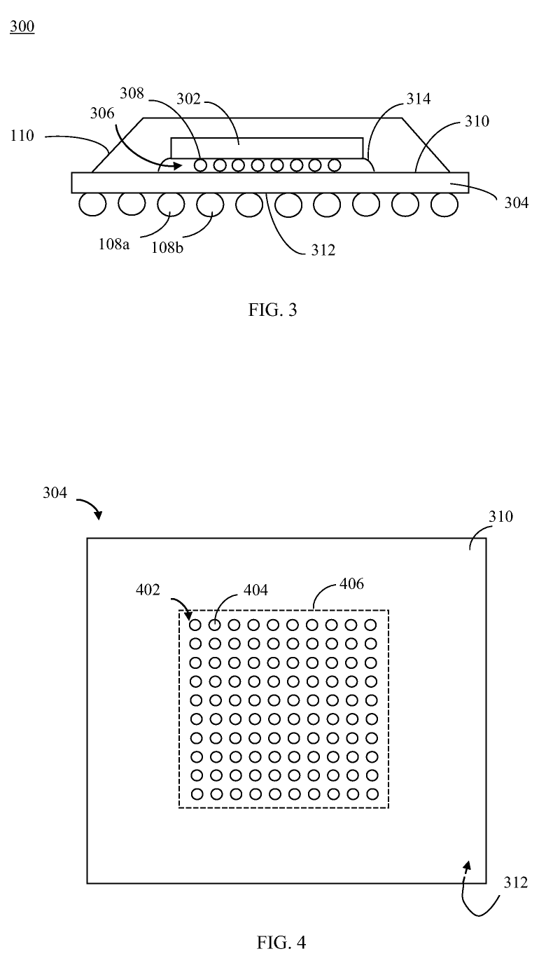

FIG. 3 shows another type of BGA package, referred to as a “flip chip BGA package.” FIG. 3 shows a side cross-sectional view of a flip chip BGA package 300. As shown in FIG. 3, flip chip BGA package 300 includes an integrated circuit die/chip 302, a substrate 304, plurality of solder balls 108, a plurality of solder bumps/balls 306, an underfill material 314, and encapsulating material 110. Flip chip BGA package 300 is similar to BGA package 100 shown in FIGS. 1 and 2, except that die 302 is a flip chip integrated circuit die/chip, and substrate 304 is a flip chip substrate. Substrate 304 is similar to substrate 104 of BGA package 100, having opposing surfaces 310 (e.g., top) and 312 (e.g., bottom), with some differences described as follows.

As shown in FIG. 3, rather than using bond wires 106 to couple signals of die 102 to substrate 104 as shown in FIG. 1, die 302 is attached to substrate 304 in a “flip chip” manner. Solder bumps 306 are formed on the signal pads/terminals of die 302. Die 302 is attached to substrate 304 in an inverted (“flipped”) orientation with respect to the attachment of die 102 to substrate 104 in FIG. 1. Die 302 is attached to substrate 304 by reflowing solder bumps 306 so that solder bumps 306 attach to corresponding pads on a (top) surface 310 of substrate 304. FIG. 4 shows a view of surface 310 of substrate 304. As shown in FIG. 4, surface 310 of substrate 304 has a mounting region 406 for a flip chip die, such as die 302. Mounting region 406 includes an array 402 of solder ball/bump pads corresponding to solder bumps 306. In the example of FIG. 4, array 402 includes a ten by ten array of pads 404. However, any number of pads 404 may be present in mounting region 406, depending on the number of solder bumps 306 on the flip chip die to be mounted thereto. When die 302 is mounted to mounting region 406 of substrate 304, solder bumps 306 attach to pads of array 402 on substrate 304. For example, a solder bump/ball 308 shown in FIG. 3 may attach to solder ball/bump pad 404 shown in FIG. 4 when die 302 is mounted to substrate 304.

Underfill material 314 may be optionally present, as shown in FIG. 3. Underfill material 314 fills in a space between die 302 and substrate 304 between solder bumps 306. Underfill material 314 may be an epoxy or any other suitable type of underfill material, as would be known to persons skilled in the relevant art(s). When underfill material 314 is not present, encapsulating material 110 may instead fill in the space between die 302 and substrate 304 between solder bumps 306.

As integrated circuits are becoming increasingly more complex, the number of power, ground, and I/O pads/terminals of integrated circuit dies is also increasing. It is becoming increasingly more difficult to interface this increased number of power, ground, and I/O pads/terminals of integrated circuit dies with package substrates. For example, with regard to BGA package 100 of FIG. 1, as the number of pads/terminals 116 of die 102 increases, an increased number of bond wires 106 and a more complex arrangement of bond wires 106 is correspondingly required. For example, in order to accommodate the increased number of bond wires 106, the lengths of some bond wires may need to be increased. The increased lengths enable the lengthened bond wires to reach over other bond wires 106 to make contact with surface 112 of substrate 104 without shorting with shorter bond wires 106. However, the increased lengths cause a greater IR (current×voltage) drop through the lengthened bond wires 106, which is undesirable. With regard to BGA package 300 of FIG. 3, as the number solder bumps 306 increases due to the increased number of power, ground, and I/O pads/terminals, the size of array 402 shown in FIG. 4 must correspondingly increase. This may lead to substrate 304 requiring additional routing layers to enable all pads 404 to be routed out of array 402. Thus, in either of BGA packages 100 and 300, an increase in number of power, ground, and I/O signals of the die can lead to more complex and expensive package configurations, with a decreased quality of electrical function.

Embodiments of the present invention enable an increased number of power, ground, and I/O signals for a die in an integrated circuit package, without substantially increasing package complexity and cost. Example embodiments are further described in the following section.

### Example Embodiments

The example embodiments described herein are provided for illustrative purposes, and are not limiting. Although described below with reference to BGA packages, the examples described herein may be adapted to other types of integrated circuit packages. Including pin grid array (PGA) (e.g., a package having pins for package mounting), land grid array (LGA) (e.g., a package having pads for package mounting), and further types of integrated circuit packages that include one or more dies mounted to a substrate. Furthermore, additional structural and operational embodiments, including modifications/alterations, will become apparent to persons skilled in the relevant art(s) from the teachings herein.

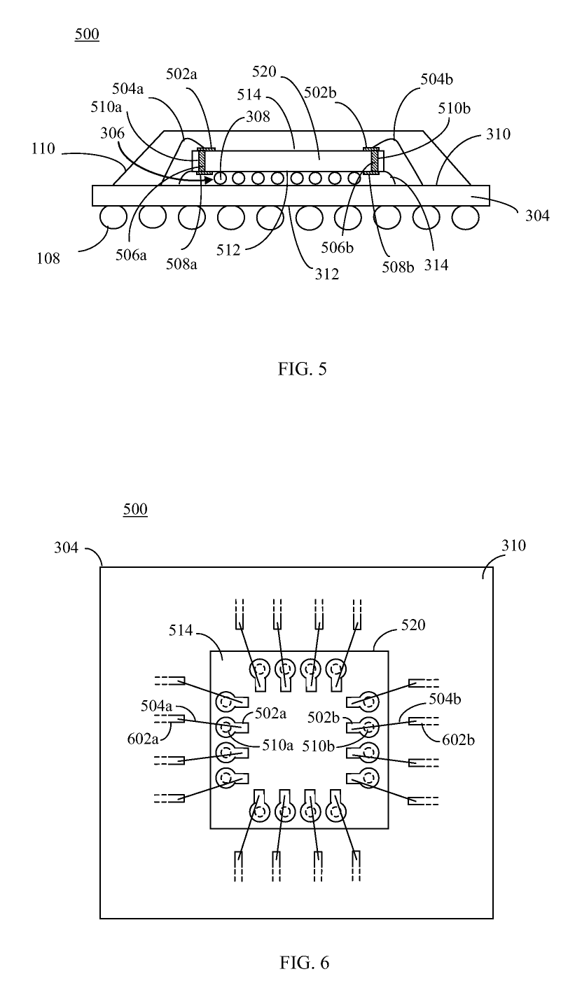

FIGS. 5 and 6 show views of a BGA package 500, according to an example embodiment of the present invention. FIG. 5 shows a side cross-sectional view of package 500, and FIG. 6 shows a top view of package 500. BGA package 500 is similar to flip chip BGA package 300 shown in FIG. 3, with differences described as follows. As shown in FIG. 5, BGA package 300 includes an integrated circuit die/chip 520, a substrate 304, bond wires (also known as “wire bonds”) 504, a plurality of solder balls 108, and an encapsulating material 110. Substrate 304 has a first (e.g., top) surface 310 that is opposed to a second (e.g., bottom) surface 312 of substrate 304.

As shown in FIG. 5, die 520 has opposing first (e.g., bottom) and second (e.g., top) surfaces 512 and 514. Surface 512 of die 520 is an active surface of die 520, having an integrated circuit formed therein. Surface 512 of die 520 is mounted to surface 310 of substrate 304 in a flip chip manner, similar to die 302 shown in FIG. 3. An array of solder bumps 306 or other suitable array of interconnects, may mount die 520 to substrate 304. Solder bumps 306 may be formed on the signal pads/terminals at surface 512 of die 520. Die 520 is attached to substrate 304 in an inverted (“flipped”) orientation with respect to the attachment of die 102 to substrate 104 in FIG. 1. Die 520 is attached to substrate 304 by reflowing solder bumps 306 so that solder bumps 306 attach to corresponding pads on surface 310 of substrate 304. Signals (e.g., power, ground, I/O, test, etc.) of die 520 are coupled to routing of substrate 304 by solder bumps 306.

As shown in FIGS. 5 and 6, die 520 has a plurality of vias 510. Vias 510 are formed through die 520, being open at surfaces 512 and 514 of die 520. As shown in FIG. 5, surface 512 of die 520 includes first electrically conductive features 508, which are coupled to corresponding signals of die 520, routed internal to die 520 to surface 512. Each of first electrically conductive features 508 is coupled to a corresponding via 510. Surface 514 of die 520 includes second electrically conductive features 502, which are each coupled to a corresponding via 510. Second electrically conductive features 502 are coupled to corresponding signals of die 520 through vias 510. An electrically conductive material 506 is present in each via 510 to form an electrically conductive path. For example, electrically conductive material 506a in via 510a forms an electrically conductive path between a first electrically conductive feature 508a on surface 512 of die 520 and a second electrically conductive feature 502a on surface 514 of die 520, and electrically conductive material 506b in via 510b forms an electrically conductive path between a first electrically conductive feature 508b on surface 512 of die 520 and a second electrically conductive feature 502b on surface 514 of die 520.

Note that electrically conductive features 502 and 508 may include any type and combination of electrical features, such as a trace, a contact pad, etc. Electrically conductive features 502 and 508 may be made of an electrically conductive material, such as copper, aluminum, silver, gold, nickel, tin, or other metal, or combination of metals/alloy.

As shown in FIGS. 5 and 6, package 500 includes bond wires 504 that couple signals at electrically conductive features 502 on surface 514 of die 520 to electrically conductive features on surface 310 of substrate 304. For example, as shown in FIG. 6, a first bond wire 504a is coupled between an electrically conductive feature 502a of die 520 to a first electrically conductive feature 602a on surface 310 of substrate 304, and a second bond wire 504b is coupled between an electrically conductive feature 502b of die 520 to a second electrically conductive feature 602b on surface 310 of substrate 304. First and second electrically conductive features 602a and 602b may be any type of electrically conductive features of substrate 304, including bond fingers, traces, pads, rings, etc.

In this manner, active surface 512 of die 520 may be flip chip mounted to substrate 304 to interface a first set of signals of die 520 to substrate 304, and bond wires 504 may interface a second set of signals at active surface 512 of die 520 with substrate 304 by coupling electrically conductive features 502 of die 520 to electrically conductive features 602 of substrate 304. Electrically conductive paths are formed from surface 512 of die 520 to surface 514 of die 520 to enable the second set of signals to be coupled to substrate 304 using bond wires 504. The embodiment of FIGS. 5 and 6 enables an increased number of signals, including power, ground, and/or I/O signals, of die 520 to be interfaced with substrate 304, and thus to be made available at solder balls 108 of package 500, without substantially increasing the complexity and cost of package 500. Furthermore, since fewer bond wires 504 may be used (because of the presence of interconnects 306), the present bond wires 504 may not need to be lengthened and/or may be routed in a less complex manner than in conventional packages, such as package 100 shown in FIG. 1.

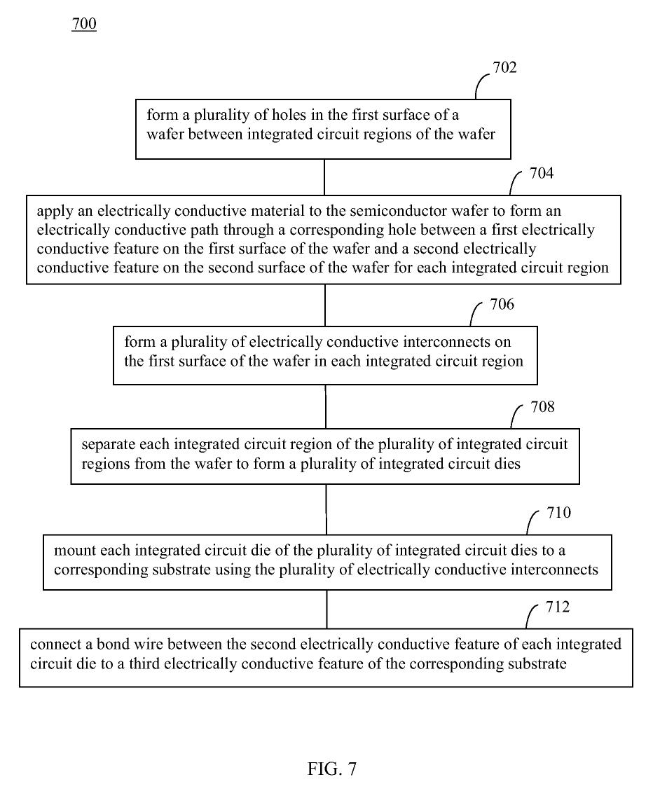

Package 500 may be assembled in any manner. For example, each package 500 may be assembled individually, or packages 500 may be assembled in parallel. For example, FIG. 7 shows a flowchart 700 providing a process for assembling integrated circuit packages, according to embodiments of the present invention. In an embodiment, package 500 shown in FIGS. 5 and 6 may be assembled according to flowchart 700, as well as other package embodiments described elsewhere herein. Other structural and operational embodiments will be apparent to persons skilled in the relevant art(s) based on the discussion regarding flowchart 700. Note that conventional steps for assembling an integrated circuit package are not shown in FIG. 7 for purposes of brevity, and because they will be known to persons skilled in the relevant art(s). Such steps may include attaching solder balls (e.g., solder balls 108) to substrate 304, encapsulating a die on substrate 304 (e.g., with encapsulating material 110), applying underfill material (e.g., underfill material 314), etc. Furthermore, note that the steps of flowchart 700 do not necessarily need to be performed in the order shown in FIG. 7. Flowchart 700 is described as follows.

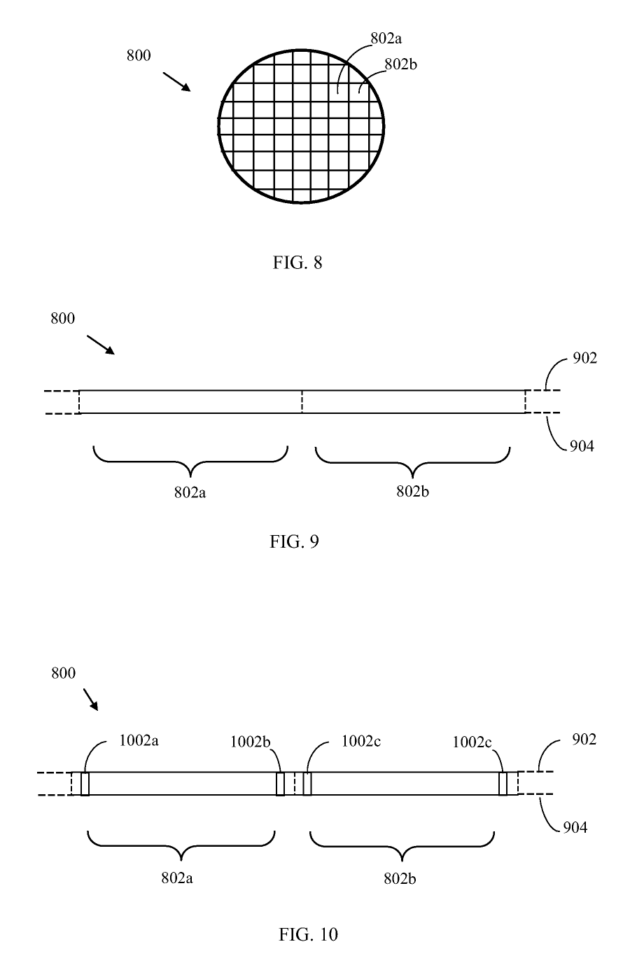

Flowchart 700 begins with step 702. In step 702, a plurality of holes is formed in the first surface of a wafer between integrated circuit regions of the wafer. For example, FIG. 8 shows a wafer 800. Wafer 800 may be silicon, gallium arsenide, or other wafer type. As shown in FIG. 8, wafer 800 has a surface defined by a plurality of integrated circuit (IC) regions 802 (shown as small rectangles in FIG. 8), including a first IC region 802a and a second IC region 802b. Each integrated circuit region is configured to be packaged separately into a separate package according to the process of flowchart 700. FIG. 9 shows a side cross-sectional view of a portion of wafer 800, showing integrated circuit regions 802a and 802b. As shown in FIG. 9, wafer 800 has opposing first and second surfaces 902 and 904. In FIG. 9, integrated circuits are formed in surface 902 of wafer 800 (the “active” surface) for each of integrated circuit regions 802a and 802b.

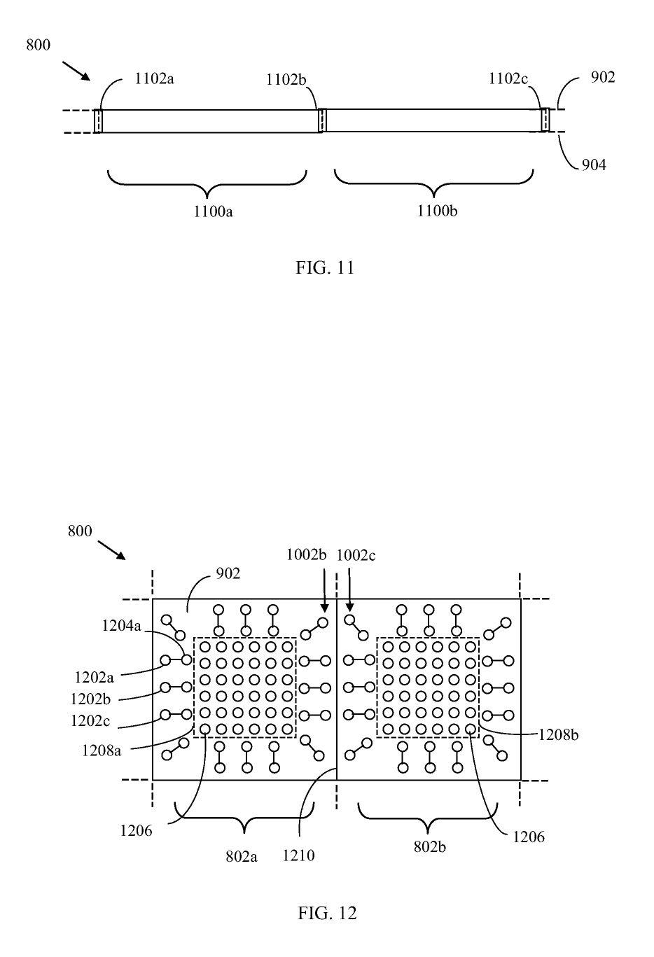

According to step 702, a plurality of holes/openings (e.g., used to form vias 510 shown in FIG. 5) is formed in wafer 800 between adjacent integrated circuit regions 802. FIGS. 10 and 11 show example hole/opening configurations, according to embodiments of the present invention. FIG. 10 shows a side cross-sectional view of the portion of wafer 800 shown in FIG. 9, with holes/openings formed therein. As shown in FIG. 10, a first row of holes 1002a and a second row of holes 1002b are formed on opposing sides of integrated circuit region 802a, and a third row of holes 1002c and a fourth row of holes 1002d are formed on opposing sides of integrated circuit region 802b. A pair of parallel rows—second and third rows of holes 1002b and 1002c—are positioned between integrated circuit regions 802a and 802b.

FIG. 11 shows an alternative hole configuration, according to another example embodiment of the present invention. FIG. 11 shows a side cross-sectional view of the portion of wafer 800 shown in FIG. 9, with the alternative configuration of holes formed therein. As shown in FIG. 11, a first row of holes 1102a and a second row of holes 1102b are formed on opposing sides of integrated circuit region 802a. Furthermore, second row of holes 1102b and a third row of holes 1102c are formed on opposing sides of integrated circuit region 802b. A single row of holes—second row of holes 1102b—is positioned between integrated circuit regions 802a and 802b.

Note that holes 1002 and 1102 may be formed in any manner, including by etching (e.g., chemical etching, photolithography, etc.), drilling (e.g., using a mechanical drill, a laser drill, etc.), punching, or other hole forming technique, as would be known to persons skilled in the relevant art(s). Furthermore, in an embodiment, holes 1002 and 1102 may be formed completely through wafer 800. In another embodiment, holes 1002 and 1102 may be formed at surface 902 partially through wafer 800. Wafer 800 may subsequently by thinned, to cause holes 1002 and 1102 to become open at surface 904 of wafer 800.

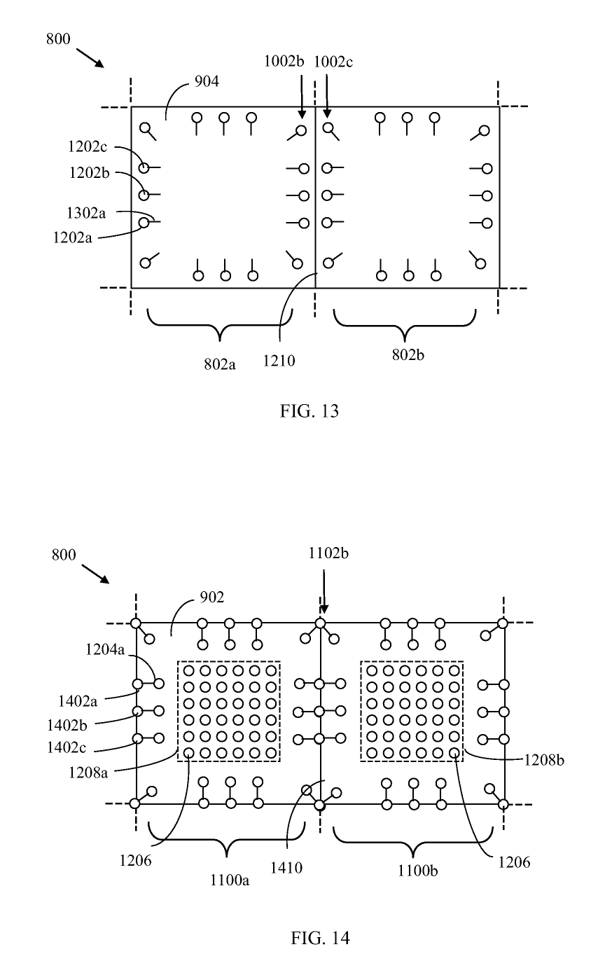

In step 704, an electrically conductive material is applied to the semiconductor wafer to form an electrically conductive path through a corresponding hole between a first electrically conductive feature on the first surface of the wafer and a second electrically conductive feature on the second surface of the wafer for each integrated circuit region. For example, FIGS. 12 and 13 show views of surfaces 902 and 904, respectively, of the portion of wafer 800 shown in FIG. 10, according to an embodiment of the present invention. As shown in FIG. 12, a plurality of holes 1202 (formed in step 702) are formed around each of first and second integrated circuit regions 802a and 802b (e.g., holes 1202a-1202c are specifically indicated in FIG. 12). Each of holes 1202 is coupled to a first electrically conductive feature 1204 in one of first and second integrated circuit regions 802a and 802b. Each electrically conductive feature 1204 is coupled to a signal (e.g., ground, power, I/O, test, etc.) routed to surface 902 from inside the integrated circuit of the respective one of integrated circuit regions 802a and 802b.

As shown in FIG. 13, holes 1202 are also open at surface 904 of wafer 800. Each of holes 1202 is coupled to a corresponding second electrically conductive feature 1302 (shown as a short trace/pad in FIG. 13) on surface 904. An electrically conductive material is applied to partially or entirely fill holes 1202, so that electrically conductive paths are formed through holes 1202. Each electrically conductive path includes an electrically conductive feature 1204 on surface 902 of wafer 800, the electrically conductive material in one of holes 1202, and an electrically conductive feature 1302 on surface 904 of wafer 800. For instance, an electrically conductive path is formed by first electrically conductive feature 1204a (FIG. 12), hole 1202a, and second electrically conductive feature 1302a (FIG. 13). During operation of the corresponding integrated circuit, each electrically conductive path conducts a respective signal (e.g., ground, power, I/O, test, etc.) from the integrated circuit at surface 902 of wafer 800 to the corresponding second electrically conductive feature 1302 on surface 904 of wafer 800.

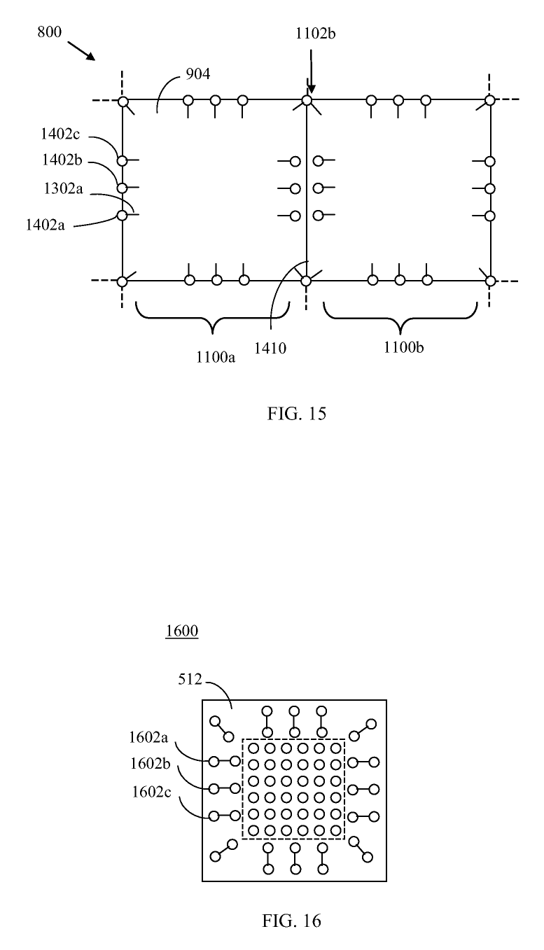

FIGS. 14 and 15 show views of surfaces 902 and 904, respectively, of the portion of wafer 800 shown in FIG. 11, according to another embodiment of the present invention. As shown in FIG. 14, a plurality of holes 1402 (formed in step 702) are formed around each of first and second integrated circuit regions 1100a and 1100b (e.g., holes 1402a-1402c are specifically indicated in FIG. 14). Each of holes 1402 is coupled to a first electrically conductive feature 1204 in one of first and second integrated circuit regions 1100a and 1100b. Each electrically conductive feature 1204 is coupled to a signal (e.g., ground, power, I/O, test, etc.) of the integrated circuit of the respective one of integrated circuit regions 1100a and 1100b.

As shown in FIG. 15, holes 1402 are also open at surface 904 of wafer 800. Each of holes 1402 is coupled to a corresponding second electrically conductive feature 1302 on surface 904. An electrically conductive material is applied to partially or entirely fill holes 1402, so that electrically conductive paths are formed. Each electrically conductive path includes an electrically conductive feature 1204 on surface 902 of wafer 800, the electrically conductive material in one of holes 1402, and an electrically conductive feature 1302 of surface 904 of wafer 800. For instance, an electrically conductive path is formed by first electrically conductive feature 1204a (FIG. 14), hole 1402a, and second electrically conductive feature 1302a (FIG. 15). During operation of the corresponding integrated circuit, each electrically conductive path conducts a respective signal (e.g., ground, power, I/O, test, etc.) from the integrated circuit at surface 902 of wafer 800 to the corresponding second electrically conductive feature 1302 on surface 904 of wafer 800.

In embodiments, the electrically conductive material may be applied to completely fill holes 1202 (FIG. 12) and holes 1402 (FIG. 14), or may be applied to partially fill holes 1202 and 1402. For example, in an embodiment, the electrically conductive material may be applied to plate an inner surface of holes 1202 and/or 1402. Note that in step 704, the electrically conductive material applied to holes 1202 and 1402 may additionally be applied to form first and second electrically conductive features 1204 and 1302. The electrically conductive material may be any suitable electrically conductive material, including a metal such as aluminum, copper, silver, gold, nickel, tin, or other metal, or a combination of metals/alloy, such as a solder.

In step 706, a plurality of electrically conductive interconnects is formed on the first surface of the wafer in each integrated circuit region. For example, as shown in FIG. 12, a plurality of electrically conductive interconnects 1206 (e.g., solder bumps, solder balls, etc.) are formed on surface 902 for each of integrated circuit regions 802a and 802b (e.g., in regions 1208a and 1208b, respectively). Likewise, as shown in FIG. 14, electrically conductive interconnects 1206 are formed on surface 902 for each of integrated circuit regions 1102a and 1102b. Note that steps 704 and 706 may be optionally performed during the same process step, or during different process steps, in embodiments.

In step 708, each integrated circuit region of the plurality of integrated circuit regions is separated from the wafer to form a plurality of integrated circuit dies. For example, integrated circuit regions 802a and 802b shown in FIGS. 12 and 13 (and further integrated circuit regions of wafer 800) may be separated from wafer 800 to form separate dies. Integrated circuit regions 802a and 802b may be separated from each other along a line 1410 shown in FIGS. 12 and 13 between rows of holes 1002b and 1002c. For example, in an embodiment, integrated circuit regions 802a and 802b may each be separated from wafer 800 to form an integrated circuit die 1600 shown in FIG. 16 (active surface 512 of die 1600 is shown in FIG. 16). As shown in FIG. 16, die 1600 includes a plurality of electrically conductive vias 1602 formed by steps 702 and 704. Die 1600 may have any number of vias 1602, depending on the number of holes 1202 formed in step 702.

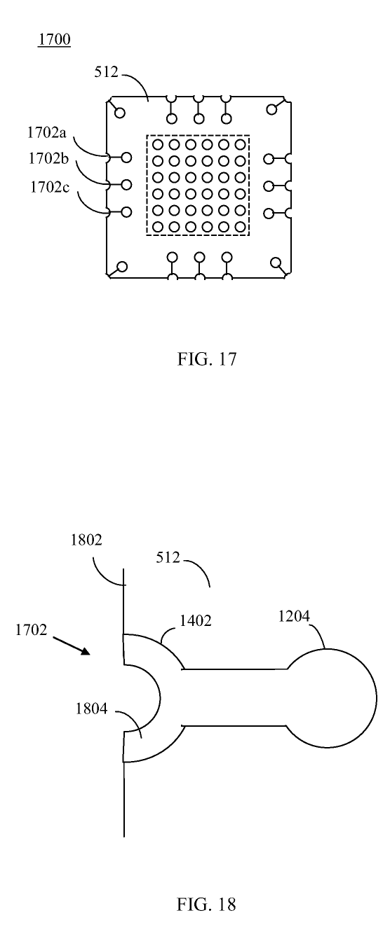

Likewise, integrated circuit regions 1100a and 1100b shown in FIGS. 14 and 15 (and further integrated circuit regions of wafer 800) may be separated from wafer 800 to form separate dies. For instance, integrated circuit regions 1100a and 1100b may be separated from each other along a line 1410 shown in FIGS. 14 and 15 which passes through each hole in the row of holes 1102b, to separate each hole. Integrated circuit regions 1100a and 1100b may each be separated from wafer 800 to form an integrated circuit die 1700 shown in FIG. 17 (active surface 512 of die 1700 is shown in FIG. 17). By separating adjacent integrated circuit regions 1100 through the bordering row of electrically conductive material filled holes 1102, electrically conductive indentations 1702 are formed in the edges of die 1700. Example indentations 1702a-1702c are indicated in FIG. 17. Each indentation 1702 is a portion of the hole formed in step 702. Indentation 1702 is formed by separating die 1700 from wafer 800 during step 708, when a hole through wafer 800 is cut in half (or in other proportion) during step 708.

For instance, FIG. 18 shows an expanded view of an example indentation 1702 formed in an edge 1802 of a die (e.g., die 1700 of FIG. 17), according to an embodiment of the present invention. FIG. 18 shows active surface 512 of die 1700. Indentation 1702 is a portion of a hole 1402 that was formed in step 702. As shown in FIG. 18, has a semi-cylindrical shape. Indentation 1702 may be any portion of hole 1402, including less than a half of hole 1402, a half of hole 1402 (as shown in FIG. 18), or more than a half of hole 1402. As further shown in FIG. 18, an electrically conductive material 1804 is present in indentation 1702. Electrically conductive material 1804 may cover/plate a surface of indentation 1702, or may fill indentation 1702, for example. Electrically conductive material 1802 is applied in hole 1402 in step 704, and is separated in step 708 (when hole 1402 was separated). Electrically conductive material 1802 forms an electrically conductive path through indentation 1702 from first electrically conductive feature 1204 on surface 512 of the die to a second electrically conductive feature 1302 on surface 514 (not shown in FIG. 18) of the die.

The separation of wafer 800 in step 708 may be performed in any manner, as would be known to person skilled in the relevant art(s). For example, wafer 800 may be separated into multiple die by a sawing process, a laser, an etching process, or other suitable process.

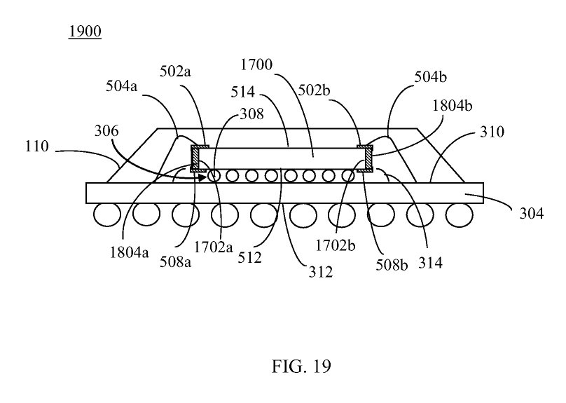

In step 710, each integrated circuit die of the plurality of integrated circuit dies is mounted to a corresponding substrate using the plurality of electrically conductive interconnects. In embodiments, die 1600 shown in FIG. 16 and/or die 1700 shown in FIG. 17 may be attached to a substrate in a flip chip manner as shown for die 520 in FIG. 5. For example, FIG. 19 shows a side cross-sectional view of a BGA package 1900, according to an example embodiment of the present invention. BGA package 1900 is generally similar to BGA package 500 shown in FIG. 5, except that die 1700 is mounted to substrate 304 rather than die 520. As shown in FIG. 19, die 1700 has first and second indentations 1702a and 1702b that provide respective electrically conductive paths between surfaces 512 and 514 of die 1700.

Any suitable process may be used to mount die 1600 or die 1700 to a substrate, including a pick-and-place apparatus, or other process and/or apparatus, as would be known to persons skilled in the relevant art(s).

In step 712, a bond wire is connected between the second electrically conductive feature of each integrated circuit die to a third electrically conductive feature of the corresponding substrate. For example, in an embodiment, bond wires 504 may be coupled between electrically conductive features 502 (e.g., shown in FIGS. 5, 6, and 19) or 1302 (e.g., shown in FIGS. 13 and 15) on surface 514 of die 1600 or die 1700 and electrically conductive features (e.g., electrically conductive features 602 shown in FIG. 6) on surface 310 of substrate 304.

In this manner, a signal at surface 512 of a die may be conducted by a first electrically conductive feature on surface 512, through an electrically conductive material in a via or indentation, through a second electrically conductive feature on surface 514 of the die, through a bond wire 504, to a third electrically conductive feature 602 on surface 310 of substrate 304. Substrate 310 may contain routing/vias to route the signal from the third electrically conductive feature 602 to solder balls 108 (or pins, pads, or other interconnections on second surface 312 of substrate 304).

Any suitable process may be used to connect bond wires between dies and substrates, as would be known to persons skilled in the relevant art(s), including using known wire bonding machines or other techniques. Second electrically conductive features 502/1302 may be configured for wire bonding, including being formed to have a post, a pad, or other feature to enable/enhance bond wire connection.

### Conclusion

While various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the following claims and their equivalents

What is claimed is:

1. An integrated circuit package, comprising:
a substrate having opposing first and second surfaces;
an integrated circuit die having opposing first and second surfaces;
a plurality of electrically conductive interconnects on the first surface of the die that mount the die to the first surface of the substrate;
an electrically conductive material that forms an electrically conductive path from a first electrically conductive feature on the first surface of the die to a second electrically conductive feature on the second surface of the die; and
a bond wire that couples the second electrically conductive feature to a third electrically conductive feature on the first surface of the substrate.

2. The integrated circuit package of claim 1, further comprising:
a via through the die that is open at the first and second surfaces of the die;
wherein the electrically conductive material is in the via to form the electrically conductive path through the via from the first electrically conductive feature to the second electrically conductive feature.

3. The integrated circuit package of claim 2, wherein the electrically conductive material fills the via.

4. The integrated circuit package of claim 2, wherein the electrically conductive material coats a surface of the via.

5. The integrated circuit package of claim 1, wherein the integrated circuit die has an edge that includes an indentation that extends from the first surface of the die to the second surface of the die; and
wherein the electrically conductive material is in the indentation to form the electrically conductive path through the indentation from the first electrically conductive feature to the second electrically conductive feature.

6. The integrated circuit package of claim 1, further comprising:
a plurality of distinct electrically conductive paths formed by the electrically conductive material between a first plurality of electrically conductive features on the first surface of the die to a second plurality of electrically conductive features on the second surface of the die; and
a plurality of bond wires that couple the first plurality of electrically conductive features to the second plurality of electrically conductive features on the first surface of the substrate.

7. The integrated circuit package of claim 1, wherein the plurality of electrically conductive interconnects comprises a plurality of electrically conductive bumps.

8. The integrated circuit package of claim 1, further comprising:
a plurality of solder balls on the second surface of the substrate configured to mount the package to a circuit board.

9. The integrated circuit package of claim 1, further comprising:
a plurality of pins on the second surface of the substrate configured to mount the package to a circuit board.

10. A method for assembling integrated circuit packages, comprising:
receiving a semiconductor wafer having opposing first and second surfaces, the wafer having a plurality of integrated circuit regions;
forming a plurality of holes in the first surface of the wafer between the integrated circuit regions;
applying an electrically conductive material to the semiconductor wafer to form an electrically conductive path through a corresponding hole between a first electrically conductive feature on the first surface of the wafer and a second electrically conductive feature on the second surface of the wafer;
forming a plurality of electrically conductive interconnects on the first surface of the wafer in each integrated circuit region;
separating each integrated circuit region of the plurality of integrated circuit regions from the wafer to form a plurality of integrated circuit dies;
mounting each integrated circuit die of the plurality of integrated circuit dies to a corresponding substrate using the plurality of electrically conductive interconnects; and
connecting a bond wire between the second electrically conductive feature of each integrated circuit die to a third electrically conductive feature of the corresponding substrate.

11. The method of claim 10, wherein said forming a plurality of holes comprises:
forming parallel first and second rows of holes in the first surface of the wafer between a first integrated circuit region and a second integrated circuit region; and
wherein said separating comprises:
separating the wafer between the first and second rows of holes to form a first integrated circuit die that includes the first integrated circuit region and the first row of holes, and to form a second integrated circuit die that includes the second integrated circuit region and the second row of holes.

12. The method of claim 11, wherein the electrically conductive material is in a first hole of the first row of holes to form an electrically conductive path through the first hole between corresponding first and second electrically conductive features of the first integrated circuit die; and
wherein the electrically conductive material is in a second hole of the second row of holes to form an electrically conductive path through the second hole between corresponding first and second electrically conductive features of the second integrated circuit die.

13. The method of claim 10, wherein said forming a plurality of holes comprises:
forming a row of holes in the first surface of the wafer between a first integrated circuit region and a second integrated circuit region; and
wherein said separating comprises:
separating the wafer at the row of holes to form a first integrated circuit die that includes the first integrated circuit region and has an edge that includes a first plurality of indentations corresponding to the row of holes, and to form a second integrated circuit die that includes the second integrated circuit region and has an edge that includes a second plurality of indentations corresponding to the row of holes.

14. The method of claim 13, wherein the electrically conductive material is in a first indentation of the first plurality of indentations to form an electrically conductive path through the first indentation between corresponding first and second electrically conductive features of the first integrated circuit die; and
wherein the electrically conductive material is in a second indentation of the second plurality of indentations to form an electrically conductive path through the second indentation between corresponding first and second electrically conductive features of the second integrated circuit die.

15. The method of claim 10, further comprising:
forming a plurality of solder balls on a surface of each substrate configured to mount each substrate to a circuit board.

16. The method of claim 10, further comprising:
a plurality of pins on a surface of each substrate configured to mount each substrate to a circuit board.

17. A semiconductor die, comprising:
a semiconductor material having opposing first and second surfaces;
an integrated circuit defined in the first surface;
a plurality of electrically conductive interconnects on the first surface configured to mount the die to a substrate; and
an electrically conductive material that forms an electrically conductive path from an electrically conductive feature on the first surface of the die to bond wire pad on the second surface of the die.

18. The semiconductor die of claim 17, further comprising:
a via through the die that is open at the first and second surfaces of the die;
wherein the electrically conductive material is in the via to form the electrically conductive path through the via from the electrically conductive feature to the bond wire pad.

19. The semiconductor die of claim 17, further comprising:
an indentation in an edge of the die that extends from the first surface of the die to the second surface of the die;
wherein the electrically conductive material is in the indentation to form the electrically conductive path through the indentation from the electrically conductive feature to the bond wire pad.

20. The semiconductor die of claim 19, wherein the indentation has a semicylindrical shape.
